(19) United States
(12) Patent Application Publication
(10) Pub. No.: US 2002/0021726 A1
(43) Pub. Date: Feb. 21, 2002

(54) Vertical resonator laser diode with a small aperture opening

(76) Inventor: Torsten Wipiejewski, Santa Barbara, CA (US)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/939,999

(22) Filed: Aug. 27, 2001

Related U.S. Application Data
(63) Continuation of application No. PCT/DE00/00544, filed on Feb. 25, 2000.

(30) Foreign Application Priority Data
Feb. 26, 1999 (DE) 199 08 425.4

(51) Int. Cl. H01S 5/00; H01S 3/08

(52) U.S. Cl. 372/46; 372/96

(57) ABSTRACT

A vertical resonator laser diode includes an active layer sequence for generating laser radiation, which is disposed between a first Bragg reflector layer sequence and a second Bragg reflector layer sequence, each having a plurality of mirror pairs. The two Bragg reflector layer sequences form a laser resonator. The two Bragg reflector layer sequences and the active layer sequence are disposed between a first electrical contact layer and a second electrical contact layer. One of the two Bragg reflector layer sequences is partially transmissive to the laser radiation generated in the active layer sequence. A light exit opening or aperture opening in the first electrical contact layer is substantially smaller than a pumped active region of the active layer sequence. A current aperture stop is provided in at least one mirror pair of one of the two Bragg reflector layer sequences. Therefore, substantially only the fundamental mode of the laser diode is emitted during operation.

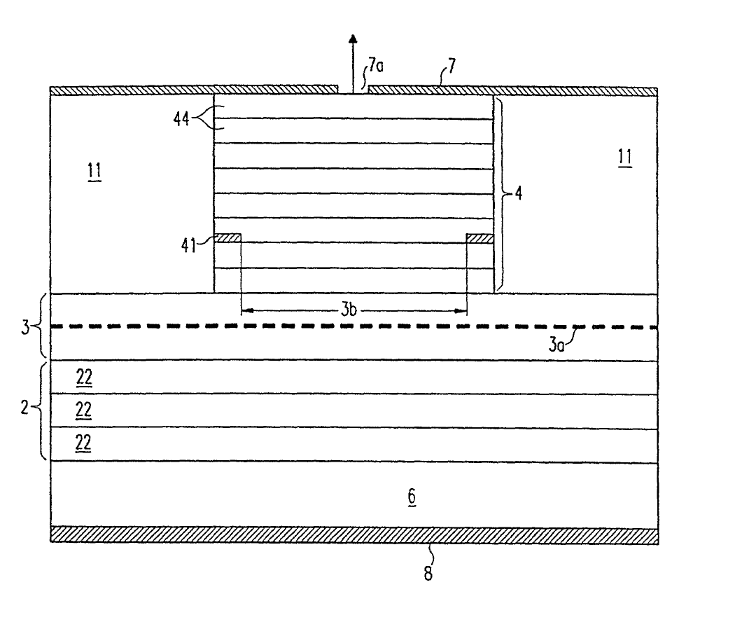

### CROSS-REFERENCE TO RELATED APPLICATION

This application is a continuation of copending International Application No. PCT/DE00/00544, filed Feb. 25, 2000, which designated the United States.

### BACKGROUND OF THE INVENTION

Field of the Invention

The invention relates to a vertical resonator laser diode, including an active layer sequence for generating laser radiation. The active layer sequence is disposed between a first Bragg reflector layer sequence and a second Bragg reflector layer sequence forming a laser resonator and each having a plurality of mirror pairs. The two Bragg reflector layer sequences and the active layer sequence are disposed between a first electrical contact layer on the light exit side and a second electrical contact layer on the substrate side. The Bragg reflector layer sequence on the light exit side is partially transmissive to the laser radiation generated in the active layer sequence. A light exit opening formed in the first contact layer has a diameter substantially smaller than a pumped active region of the active layer sequence.

Both in semiconductor lasers and in LEDs, light output power normally increases continuously with rising operating current. Although lasers have a laser threshold, above the laser threshold the light output power increases continuously with rising operating current. However, numerous applications are conceivable in which laser diodes with a pronounced threshold response would be required or desirable. That threshold response is to be distinguished in that below a specific value of the injection or operating current of the laser diode the light output power of the latter is as low as possible, whereas above that current value it is to assume a constant value, which is independent of the current value as far as possible.

Particularly in vertical resonator laser diodes (VCSELs), thermal saturation of the optical output power can be observed once a specific current value is reached. However, beyond that current value the light output power decreases rapidly in such a way that the desired current-independent output power is not present.

A VCSEL component mentioned at the outset is fundamentally known from an article entitled “Low Resistance and Large Current Range CW Single-Mode Top Surface-Emitting Laser with Small Window, by Guotong Du et al., in Opt. Quant. Electron. pages 745-749 (1993). Optimization of the properties to the respective application is possible in that case only with a substantial outlay.

In a publication entitled “Transverse Mode Control of Vertical-Cavity Top-Surface-Emitting Lasers” by R. A. Morgan et al. in IEEE Photonics Technology Letters, 5 (1993) April, No. 4, New York, pages 374-377, a vertical resonator laser diode is described in which an active layer sequence for generating laser radiation is disposed between two Bragg reflector layer sequences. Each of the Bragg reflector layer sequences has a plurality of mirror pairs. The two Bragg reflectors form a resonator and are disposed between a first electrical contact layer on the light exit side and a second electrical contact layer on the substrate side. The Bragg reflector on the light exit side is partially transmitting to the laser radiation being generated. It is further described that transverse modes in the laser activity can be largely suppressed by selection of a diameter of a light exit opening which is formed in the first contact layer and is substantially smaller than a pumped active region of the active layer sequence. Furthermore, it is provided in the laser diode described therein that a current aperture stop is provided in a mirror pair in order to limit the pumped active region by focussing the operating current.

Again, U.S. Pat. No. 5,493,577 describes just such a vertical resonator laser diode in which the Bragg reflector is structured in the shape of a mesa on the light exit side, and has a current stop in that region formed by partial oxidation.

### SUMMARY OF THE INVENTION

It is accordingly an object of the invention to provide a vertical resonator laser diode with a small aperture opening, which overcomes the hereinafore-mentioned disadvantages of the heretofore-known devices of this general type and which is improved in comparison with the known vertical resonator laser diodes.

With the foregoing and other objects in view there is provided, in accordance with the invention, a vertical resonator laser diode, comprising a first electrical contact layer on a light exit side and a second electrical contact layer on a substrate side. The first electrical contact layer has a light exit opening with a given diameter formed therein. A first Bragg reflector layer sequence and a second Bragg reflector layer sequence are disposed between the electrical contact layers and form a laser resonator. Each of the Bragg reflector layer sequences has a plurality of mirror pairs. An active layer sequence is disposed between the electrical contact layers and is disposed between the Bragg reflector layer sequences, for generating laser radiation. The active layer sequence has a pumped active region with a diameter substantially greater than the given diameter. One of the Bragg reflector layer sequences is disposed on the light exit side, structured in the shape of a mesa and partially transmissive to the laser radiation generated in the active layer sequence. A current aperture stop is disposed in one of the mirror pairs of the Bragg reflector layer sequence on the light exit side, for limiting the pumped active region by focusing operating current flowing through the active layer sequence during operation of the vertical resonator laser diode.

In the invention to be described herein, an optical output power of an optical component in the form of a vertical resonator laser diode (VCSEL) which is approximately constant over large regions of the injection or operating current is achieved by virtue of the fact that the laser diode has a relatively small light exit or aperture opening for the output radiation. The active pumped region has a substantially larger diameter, which is limited by a current aperture in the active region. The aperture opening or current aperture is intended in this case to pass substantially only the light of the fundamental mode. In contrast, the light of the higher transverse modes of the VCSEL is to be blocked off.

The diameter of the active pumped region of the VCSEL can be optimized for the respective application. However, in most cases it will lie in the range of from 10 μm to 20 μm. This relatively large diameter ensures a relatively low electric resistance of the VCSEL. In contrast, the light exit or aperture opening has a diameter of 5 μm, for example. The size of the aperture is likewise optimized for the respective application. The production process for this specific VCSEL structure requires only a modified mask layout, and the processing can be performed in a way that is entirely analogous to conventional structures.

The total light output power of conventional VCSEL structures rises with increasing current in an approximately linear way. In this case, it is the fundamental mode which is first to oscillate in most cases. Higher transverse modes also start to oscillate with rising current. The increase in the total light power is effected in this case mainly by the incipient oscillation of the higher modes. The fundamental mode rises relatively quickly to a saturation value, which does not change substantially with increasing current. The current aperture stop essentially acts as a mode filter in order to pass the fundamental mode present in the saturation, and to essentially block all other modes.

The invention therefore proceeds from the finding that the light intensity of the fundamental mode rises relatively quickly to a saturation value, and the further rise in the total light power is essentially to be ascribed to the higher transverse modes. The desired characteristic of the laser diode can therefore be achieved by virtue of the fact that, of the total mode spectrum, it is only the fundamental mode which is emitted outward, while the remaining modes are blocked.

Other features which are considered as characteristic for the invention are set forth in the appended claims.

Although the invention is illustrated and described herein as embodied in a vertical resonator laser diode with a small aperture opening, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

The FIGURE of the drawing is a diagrammatic, sectional view of an exemplary embodiment of an epitaxial layer structure of a vertical resonator laser diode according to the invention.

### DESCRIPTION OF THE PREFERRED EMBODIMENTS

Referring now in detail to the single FIGURE of the drawing, there is seen a vertical resonator laser diode having a first, lower Bragg reflector laser sequence 2, which is constructed from individual identical mirror pairs 22 and is located on a GaAs substrate 6. The mirror pairs are respectively formed of two AlGaAs layers of different band gaps. In the same way, a second, upper Bragg reflector layer sequence 4 is constructed from corresponding mirror pairs 44. An active layer sequence 3 which has an active zone 3a is embedded between the lower and the upper Bragg reflector layer sequences. The material of the active layer sequence 3 can be selected, for example, in such a way that the emission wavelength of a laser diode is 850 nm. A first metallization layer 7, which is used for an electrical connection of a p-doped side of the laser diode, is located on a top surface. The first metallization layer 7 has a central aperture or light exit opening 7a for the passage of the laser radiation. An n-doped side of the diode is usually connected electrically through a second metalization layer 8, which makes contact with the substrate 6.

In the exemplary embodiment, the mirror pair 44 of the upper Bragg reflector layer sequence 4 contains what is referred to as a current aperture stop 41. The current aperture stop 41 ensures that there is a lateral current limitation, and thereby defines an actual active pumped region 3b in the active zone 3a. Current flow is limited to an opening region of the current aperture 41. The pumped region 3b is therefore situated substantially directly below this opening region in the active zone 3a. The current aperture 41 can be produced in a known way by partially oxidizing the AlGaAs layers of the relevant mirror pair, or by ion or proton implantation. It is also possible for a plurality of current apertures to be provided.

The upper Bragg reflector layer sequence 4 of the laser diode is structured in the form of a mesa structure above the active layer 3. The mesa-shaped upper Bragg reflector layer sequence 4 is surrounded laterally by a suitable passivation layer 11 after the at least one current aperture 41 has been formed.

The diameter of the light exit or aperture opening 7a in the upper metalization layer 7 is substantially smaller than the pumped region 3b of the active layer 3a. For example, the aperture opening 7a has a diameter of 5 μm, whereas the diameter of the region or light-emitting surface 3b is 10-20 μm or more. The result of this configuration is that it is only essentially the light of the fundamental mode (LP₀₁ mode) that can pass the aperture opening 7a. The other vibrational modes which are generated are blocked by the first metalization layer 7. Consequently, the total light power of the laser diode is determined purely and simply by the fundamental mode. When the latter reaches a saturation region with the rise in the operating current, the total light power assumes a constant value which no longer varies even with a further rising operating current.

Thus, the invention creates a laser diode with a weighted characteristic. In the case of current values below the laser threshold, the laser diode essentially emits no output radiation, or only one of very low intensity. With the increase in the operating current, the laser threshold is exceeded and the intensity of the output radiation initially rises very rapidly, but then assumes a saturation value. The output intensity remains at an approximately constant value above the saturation value.

I claim:

1. A vertical resonator laser diode, comprising:
a first electrical contact layer on a light exit side and a second electrical contact layer on a substrate side, said first electrical contact layer having a light exit opening with a given diameter formed therein;
a first Bragg reflector layer sequence and a second Bragg reflector layer sequence disposed between said electrical contact layers and forming a laser resonator, each of said Bragg reflector layer sequences having a plurality of mirror pairs;
an active layer sequence disposed between said electrical contact layers and disposed between said Bragg reflector layer sequences, for generating laser radiation, said active layer sequence having a pumped active region with a diameter substantially greater than said given diameter;
one of said Bragg reflector layer sequences being disposed on said light exit side, structured in the shape of a mesa and partially transmissive to the laser radiation generated in said active layer sequence; and
a current aperture stop disposed in one of said mirror pairs of said Bragg reflector layer sequence on said light exit side, for limiting said pumped active region by focusing operating current flowing through said active layer sequence during operation of the vertical resonator laser diode.

2. The vertical resonator laser diode according to claim 1, wherein said diameter of said pumped active region is at least twice as large as said given diameter of said light exit opening.

3. The vertical resonator laser diode according to claim 1, wherein said diameter of said pumped active region is greater than said given diameter of said light exit opening by a factor of two to four.

4. The vertical resonator laser diode according to claim 2, wherein said diameter of said pumped active region is 10-20 μm and said given diameter of said light exit opening is approximately 5 μm.
